(19) United States
(12) Patent Application Publication
(10) Pub. No.: US 2023/0326740 A1
(43) Pub. Date: Oct. 12, 2023

(54) SUBSTRATE PROCESSING METHOD

(71) Applicant: SAMSUNG ELECTRONICS CO., LTD., SUWON-SI (KR)

(72) Inventors: MINJUNG KIM, HWASEONG-SI (KR); HYUNGSUK MOON, SEONGNAM-SI (KR); SEUNGKOO SHIN, POHANG-SI (KR); SANGHWANG PARK, BUSAN (KR); HYEJOO YOON, SEONGNAM-SI (KR)

(73) Assignee: POSTECH RESEARCH AND BUSINESS DEVELOPMENT FOUNDATION, POHANG-SI (KR)

(21) Appl. No.: 17/994,181

(22) Filed: Nov. 25, 2022

(30) Foreign Application Priority Data
Apr. 12, 2022 (KR) 10-2022-0045065

(51) Int. Cl. H01L 21/02; H01L 21/268

(52) U.S. Cl. CPC H01L 21/02126; H01L 21/02595; H01L 21/02532; H01L 21/268

(57) ABSTRACT

A substrate processing method includes; forming a silicon film on a substrate, irradiating the silicon film with microwaves, and soaking the silicon film in liquid heavy water.

### CROSS-REFERENCE TO RELATED APPLICATION

This application claims priority under 35 U.S.C. § 119 to Korean Patent Application No. 10-2022-0045065 filed on Apr. 12, 2022 in the Korean Intellectual Property Office, the subject matter of which is hereby incorporated by reference in its entirety.

### BACKGROUND

### 1. Field

The inventive concept relates generally to substrate processing methods.

### 2. Description of Related Art

Contemporary and emerging semiconductor devices are characterized by increasing integration density. And accordingly, the physical sizes of constituent elements and components have been reduced. Given smaller and smaller element and component sizes, increasingly small defects tend to increasingly degrade performance of semiconductor devices.

### SUMMARY

In one aspect, embodiments of the inventive concept provide a substrate processing method that improves stability of a silicon film.

In some embodiments the inventive concept provides a substrate processing method including; forming a silicon film on a substrate, soaking the substrate on which the silicon film is formed in liquid heavy water, and irradiating the silicon film with microwaves while the substrate soaks in the liquid heavy water.

In some embodiments the inventive concept provides a substrate processing method including; forming a silicon film on a substrate, irradiating the silicon film with microwaves, and soaking the silicon film in liquid heavy water.

In some embodiments the inventive concept provides a substrate processing method including; forming a first material layer on a substrate, and forming a second material layer from the first material layer by irradiating the first material layer with microwaves and soaking the first material layer in liquid heavy water (D₂O), wherein the first material layer includes a first compound of SiₓO_{y}H_{z}, wherein each of x, y, and z is real number greater than or equal to 0 and less than 1, such that (x+y+z=1), and the second material layer includes a second compound of SiₐO_{b}H_{c}D_{d}, wherein each of a, b, c, d is a real number greater than or equal to 0 and less than 1, such that (a+b+c+d=1).

### BRIEF DESCRIPTION OF DRAWINGS

Advantages, benefits and features, as well as the making and use of the inventive concept may be better understood upon consideration of the following detailed description together with the accompanying drawings, in which:

FIG. 1 is a flowchart illustrating a substrate processing method according to embodiments of the inventive concept;

FIG. 2A is a conceptual diagram further illustrating the substrate processing method of FIG. 1;

FIG. 2B is a waveform diagram further illustrating in one example the step of irradiating the silicon film with microwaves (S12) of FIG. 1;

FIG. 3 is a chemical structure diagram illustrating a silicon film before and after substrate processing according to embodiments of the inventive concept;

FIG. 4A is a graph illustrating an infrared absorption spectrum of a silicon film before substrate processing according to the embodiments of the inventive concept;

FIG. 4B is a graph illustrating an infrared absorption spectrum of a silicon film after substrate processing method according to embodiments of the inventive concept;

FIG. 5 is a flowchart illustrating a substrate processing method according to embodiments of the inventive concept;

FIG. 6 is a conceptual diagram further illustrating the substrate processing method of FIG. 5;

FIG. 7 is a chemical structure diagram illustrating a silicon film before and after substrate processing according to embodiments of the inventive concept;

FIG. 8A is a graph illustrating an infrared absorption spectrum of a silicon film before substrate processing according to embodiments of the inventive concept;

FIG. 8B is a graph illustrating an infrared absorption spectrum of a silicon film after substrate processing according to embodiments of the inventive concept; and

FIG. 9 is a flowchart illustrating a substrate processing method according to embodiments of the inventive concept.

### DETAILED DESCRIPTION

Throughout the written description and drawings, like reference numbers and labels are used to denote like or similar elements, components, features and/or method steps. Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

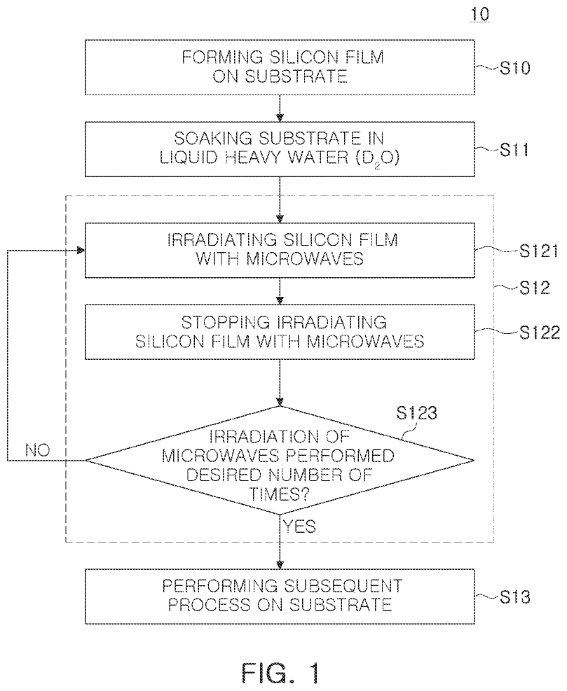

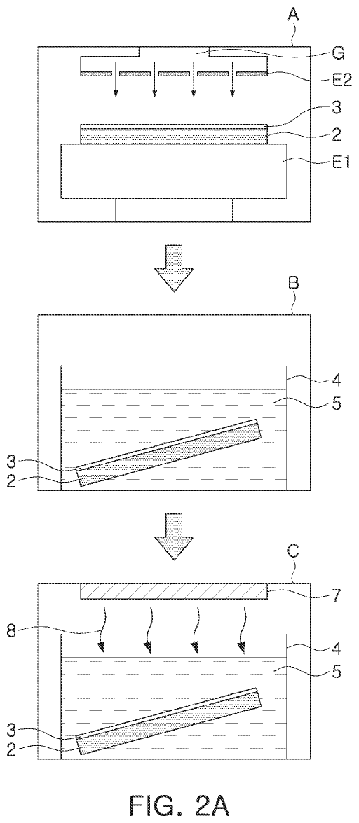

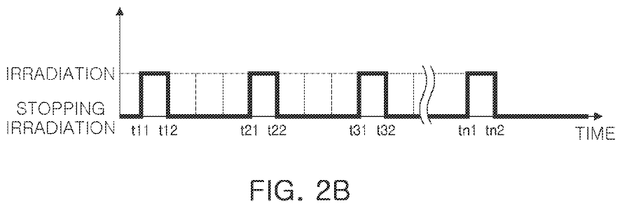

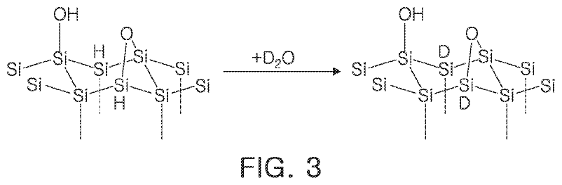

FIG. 1 is a flowchart illustrating a substrate processing method 10 according to embodiments of the inventive concept; FIG. 2A is a conceptual diagram further illustrating the substrate processing method 10 of FIG. 1; FIG. 2B is a waveform diagram further illustrating in one example the step of irradiating the silicon film with microwaves (S12) of FIG. 1; and FIG. 3 is a chemical structure diagram illustrating a silicon film before and after application of the substrate processing method 10.

Referring to FIGS. 1, 2A, 2B and 3, the substrate processing method 10 may include forming a silicon film on a substrate (S10), soaking the substrate on which the silicon film has been formed in liquid heavy water (D₂O) (S11), and irradiating the silicon film with microwaves while being soaked in the liquid heavy water (D₂O) (S12). In some embodiments, the substrate processing method 10 may further include an additional step of performing a subsequent process on the substrate (S13).

Here, the silicon film formed on the substrate may be, for example, a polycrystalline silicon film. Those skilled in the art will appreciate that there are multiple, conventionally-understood processes that may be used to form the silicon film on the substrate. For example, the silicon film may be formed using an atomic layer deposition (ALD) process, a chemical vapor deposition (CVD) process, etc. Hereafter, the process used to form the silicon film on the substrate will be generically referred to as the “formation process.”

Referring to FIG. 2A, the formation process may be used to form the silicon film 3 on the substrate 2 within a first processing chamber A. In some embodiments, the substrate 2 may be disposed between a first electrode E1 and an opposing second electrode E2 within the first processing chamber A (e.g., the substrate 2 may be loaded onto an upper surface of the second electrode E2). A gas supply unit G may also be disposed within the first processing chamber A (e.g., connected through (or proximate to) a lower surface of the second electrode E2). With this general configuration of the first processing chamber A, the silicon film 3 may be formed on the substrate 2 by application of one or more gas(es) through the gas supplying unit G while applying an electric field through a power supply unit (not shown) connected to at least one of the first electrode E1 and the second electrode E2. For example, the power supply unit may apply high frequency power to the second electrode E2 in order to generate plasma between the first electrode E1 and the second electrode E2.

In the context of one particular example of the formation process, once the substrate 2 has been loaded on the upper surface of the first electrode E1, a gas or gas mixture (e.g., silane (SiH₄), hydrogen (H₂), etc.) may be introduced into the first processing chamber through a gas supply unit G while high-frequency power is applied to the first electrode E1. Application of high-frequency power to the first electrode E1 creates a discharge between the first electrode E1 and the second electrode E2 that generates free electrons. The energized free electrons collide with atoms in the gas mixture (e.g., silane (SiH₄) and hydrogen (H₂) atoms) to form ions and radicals, and the silicon layer 3 may be formed on the exposed upper surface of the substrate 2 under the influence of the ions and radicals.

Those skilled in the art will further appreciate that the silicon film 3 may be related to any number of different purposes. For example, the silicon film 3 may be used as a channel layer, a gate electrode layer, an interconnection layer within a semiconductor device. Accordingly, the silicon film 3 may be a polycrystalline silicon film, a single crystal silicon film, an amorphous silicon film, etc.

Alternately, the silicon film 3 may be an insulating film including, for example, silicon (Si), oxygen (O) and/or hydrogen (H). Accordingly, the silicon film 3 may be a gate insulating layer, a tunnel insulating layer, etc.

However, the silicon film 3 may be formed on the substrate 2 with various defects. For example, the silicon film 3 may include dangling bonds in which unpaired electrons are not bonded to other atoms on a surface of the silicon film 3. In the case of polycrystalline silicon, dangling bonds may also be included at grain boundaries between crystals. Additionally, the silicon film 3 may include defects (e.g., vacancies formed by loss of atoms) at an interface between the silicon film 3 and another semiconductor material.

Regardless of specific cause and nature, defects may cause deterioration in the desired properties and performance characteristics of the silicon film 3. For example, hydrogen (H) may bond to a defect site in the silicon film 3, thereby degrading performance of a semiconductor device including the silicon film 3. For example, hydrogen bonded to a silicon lattice defect site has a desorption activation energy of only about 1.86 eV. Accordingly, the hydrogen may be easily desorbed by a subsequently-applied heat treatment process and outgassed as hydrogen gas (H₂). In this regard, certain heat treatment processes are commonly used to remove impurities from conductive materials, such as those including titanium (Ti), titanium nitride (TiN), or tungsten (W). When hydrogen atoms bonded to the silicon film are desorbed and outgassed as hydrogen gas (H2) as the result of a heat treatment process, the defect density of the silicon film may increase. The performance of the semiconductor device including the silicon film 3 may be further degraded due to the introduction of various contaminates caused by hydrogen outgassing.

In order to avoid these disadvantageous outcomes, substrate processing methods according to embodiments of the inventive concept provide heavy hydrogen (D) to bond to defect sites as a replacement (or substitute) for dangling bonds in a silicon film Si—D, or unstable Si—H bonds of the silicon film for Si—D bonds. This approach will be described hereafter in some additional detail.

Referring to FIGS. 1 and 2A, after the silicon film 3 has been formed on the substrate 2, the substrate 2 may be introduced into (or soaked in) liquid heavy water (D₂O) (S11). Here, the liquid heavy water (D₂O) may be a deuterium supply source for supplying heavy hydrogen (D) to the exposed silicon film.

In this regard, a bath 4 may he used to hold the liquid heavy water 5 in a second processing chamber B. That is, the substrate 2 on which the silicon film 3 has been formed may be soaked in the bath 4 containing the liquid heavy water 5 as the bath 4 is disposed in the second processing chamber B.

Liquid heavy water(D₂O) as a deuterium supply source is more stable than a gaseous deuterium supply source. As an example of the gaseous deuterium supply source, deuterated silane (SiD₄) has a property of spontaneously igniting in air without an ignition source. For this reason, when using a gaseous deuterium supply source, the deuterium supply source must have a separate safety device, and it is necessary to precisely control supply environments. In contrast, since liquid heavy water (D₂O) has low reactivity so that it is stable at room temperature, the liquid heavy water (D₂O) is easier to supply heavy hydrogen than a gaseous deuterium supply source, and may be applied to various process conditions.

Thereafter, once the substrate 2 including the silicon film 3 is soaking in the bath 4 of liquid heavy water, the silicon film 3 may be irradiated with electromagnetic energy (e.g., electrical energy transmitted in a microwave frequency band).

Referring to FIG. 2A, a microwave generator 7 disposed in (or be disposed proximate to) the second processing chamber B (or a third processing chamber C), and may be used to irradiate the silicon film 3 soaking in liquid heavy water 5 with microwave energy 8. In some embodiments, the microwave generator 7 may be a magnetron. In this manner, microwaves 8 emitted from the microwave generator 7 may irradiate the silicon film 3 formed on the substrate 2, as the substrate 2 soaks in the liquid heavy water 5. Here, however, the relative disposition, number, and type of microwave providing apparatus(es) may vary by design. Further, various transfer apparatuses may be used to convey the bath 4 between different processing chambers, as needed.

Referring to the method of FIG. 1, in some embodiments, the method step of irradiating the silicon film with microwaves while being soaked in the liquid heavy water (D₂O) (S12) may include: cyclically irradiating of the silicon film with microwaves (S121); separated by non-irradiating periods of defined duration (S122), wherein the combination of sub-steps (S121) and (S122) determine an “irradiation cycle” that may be repeatedly performed.

Referring to FIGS. 2A and 2B and assuming that the irradiation cycle is repeated n times, the silicon film 3 may be respectively irradiated with microwaves at times t11 to tn1, wherein the microwave irradiation is stopped at times t12 to tn2. Here, the variable ‘n’ may range in some embodiments between 1 and 15. That is, during each irradiation cycle, the silicon film 3 may be irradiated with microwaves (S121) for defined period of time, and then the microwave irradiation may be stopped (S122). Respective first, second, . . . to nth irradiation cycles (e.g., t11 to t12, t21 to t22, . . . to tn1 to tn2) may have the same duration or may have different durations. For example, in one embodiment, the first irradiation cycle may last between about 10 seconds to about 20 seconds, the second irradiation cycle may last between about 40 seconds to about 50 seconds, etc.

In some embodiments, earlier irradiation cycles may be equal to or longer than later irradiation cycles. Alternately, later irradiation cycles may be equal to or longer than earlier irradiation cycles.

In some embodiments, delay period(s) separating successive irradiation cycle(s) may be constant or may be varied.

In some embodiment during the method step of irradiating the silicon film with microwaves while being soaked in the liquid heavy water (D₂O) (S12), the temperature of liquid heavy water 5 in the bath 4 may be varied. For example, the temperature of the liquid heavy water (D₂O) may range from about 320K to 373K while the application of microwaves to the silicon film 3. That is, by irradiating the silicon film 3 with microwaves while being immersed in the liquid heavy water over a period of time during which the temperature of the liquid heavy water 5 is varied, Si—H bonds and dangling bonds of Si of the silicon film may be sufficiently substituted with Si—D bonds.

In some embodiments, when the silicon film 3 is a polycrystalline silicon film, as compared to, for example, an example wherein the silicon film 3 is an amorphous silicon film, the range of temperature increase for the liquid heavy water 5 may be relatively great, so that a deuterium substitution reaction may be strongly promoted.

In some embodiments, the method step of cyclically irradiating the silicon film with microwaves while being soaked in the liquid heavy water (D₂O) (S12), may further include a sub-step of determining a number of irradiation cycles (S121)/(S122) in relation to a desired number of irradiation cycles (S123). That is, so long as a desired number of microwave irradiation cycles has not been reached (S123=NO), method step S12 will repeat. However, once the desired number of microwave irradiation cycles has been reached (S123=YES), the method of FIG. 2 may proceed to the performing of an additional subsequent process (S13) or end.

In this regard, the particular duration, timing, temperature variation, and number of irradiation cycles may be varied in relation to the nature, properties and purpose of the silicon film 3 within the semiconductor device, sufficient to replace Si—H bonds (or Si dangling bonds) in the silicon film 3 with more robust Si—D bonds.

In this regard and referring to FIGS. 1, 2A and 3, a first exemplary chemical structure (left hand-side) for the silicon film 3 as formed on the substrate 2 (S10) may be converted into a more robust, second chemical structure (right hand side) by immersing the substrate n the bath 4 of liquid heavy water 5 (S irradiating the silicon film 3 with microwaves (S12).

As may be understood from FIG. 3, unstable Si—H bonds present in the silicon film 3 may be substituted with Si—D bonds by heavy hydrogen (D) obtained from the liquid heavy water (D₂O). Accordingly, heavy hydrogen may be bonded to Si dangling bonds or vacancies in the silicon film 3. However, O—H bonds, which are stable, may be maintained without being substituted with heavy hydrogen. In this manner, substrate processing methods according to embodiments of the inventive concept effectively and selectively replace unstable Si—H bonds and/or dangling Si bonds with Si-D bonds.

Using substrate processing methods according to embodiments of the inventive concept, microwave irradiation of the silicon film 3 enables selective substitution by heavy hydrogen. That is, microwave energy irradiating the silicon film 3 may cause selective vibrating of unpaired electrons. Since Si dangling bonds, vacancies, and the like, contain unpaired electrons, they will be markedly vibrated under the influence of applied microwaves. Further, unstable Si—H bonds, in which hydrogen ions and unpaired electrons of silicon are combined by electrical attraction, may be markedly vibrated by applied microwave energy. As a result, heavy hydrogen may be selectively substituted for unpaired electrons, as vibrated by the applied microwaves. In contrast, remaining stable bonds, such as O—H bonds, heavy hydrogen will not substituted. And as a further result, while maintaining stable O—H bonds, heavy hydrogen substitution may be selectively performed only for unstable Si—H bonds, Si dangling bonds, vacancy defect sites, and the like.

As noted above in some embodiments, an additional (or subsequent) process may be performed on the substrate 2 after substrate processing according to embodiments of the inventive concept. Since the unstable Si—H bonds and such have been substituted with the stable Si-D bonds, even if the subsequently applied process is performed at high-temperature (e.g., a heat-treatment process), hydrogen (H₂) outgassing will not occur. Accordingly, desired performance characteristics for the semiconductor device may be maintained and overall reliability of the semiconductor device may be enhanced.

The above-described substrate processing methods according to embodiments of the inventive concept may be applied using a variety of conventionally-available semiconductor processing equipment. For example, method step S10 may be performed in the first processing chamber A, and method steps S11 and S12 may be sequentially performed in the second processing chamber B. Alternately, method step S10 may be performed in the first processing chamber A, method step S11 may be performed in the second processing chamber B, and method step S12 may be performed in the third processing chamber C.

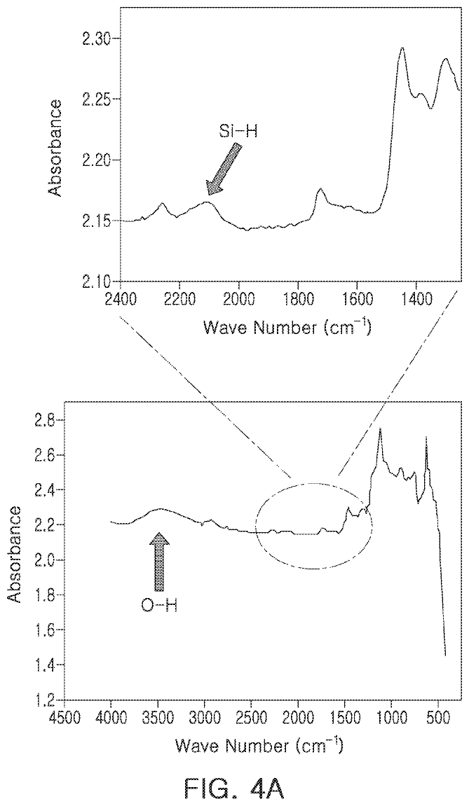

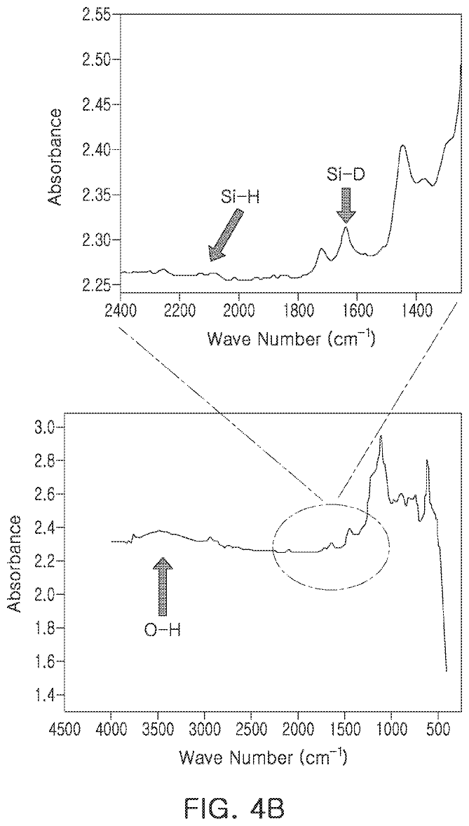

FIG. 4A is a graph illustrating an infrared absorption spectrum for the silicon film 3, as formed by method step (S10) of FIG. 1, and FIG. 4B is a graph illustrating an infrared absorption spectrum for the silicon film 3 following the second and third method steps (S11 and S12) of the method of FIG. 1.

As described above in relation to FIGS. 1 and 2A, the second method step S11 provides for the introduction of the silicon film 3 into the liquid heavy water (D₂O), then the third method step (S12) provides for the microwave irradiation of the soaking silicon film 3.

The exemplary, illustrated results of FIG. 4A were obtained by irradiating the silicon film 3 with ten (10) microwaves cycles, each lasting 15 seconds (S121) and separated by periods of 45 seconds (S122), wherein the microwave operates at a frequency of 2.45 GHz, with a wavelength of 0.122 m, and a power of 700 W.

Referring to FIG. 4A, before a heavy hydrogen (D) substitution reaction as the result of microwave irradiation in liquid heavy water (D₂O), an absorption peak appears at 2,280 cm −1 to 2,050 cm −1 and 3,400 cm⁻¹ to 3,200 cm⁻¹. It can be seen that Si—H bonds (2,280 cm−¹ to 2,050 cm−¹) and O—H bonds (3,400 cm⁻¹ to 3,200 cm⁻¹) exist in the silicon film before the heavy hydrogen (D) substitution reaction.

In contrast, referring to FIG. 4B, after a heavy hydrogen (D) substitution reaction as a result of microwave irradiation in liquid heavy water (D₂O), an absorption peak at 2,280 cm⁻¹ to 2,050 cm⁻¹ decreases, an absorption peak at 1,639 cm⁻¹ is observed, and an absorption peak at 3,400 cm⁻¹ to 3,200 cm⁻¹ is maintained. Therefore, it can be seen that Si—H bonds (2,280 cm to 2,050 cm⁻¹) are reduced, Si—D bonds (1,639 cm⁻¹) are generated, and O—H bonds (3,400 cm⁻¹ to 3,200 cm⁻¹) are maintained. Deuterium substitution by microwave irradiation may selectively substitute Si—H bonds with Si—D bonds. Thereby, while maintaining a stable O—H bond, it is possible to selectively substitute an unstable Si—H with a stable Si—D bond.

In some embodiments, the silicon film of FIG. 4A may have a formula of SiₓO_{y}H_{z}, wherein ‘x’, ‘y’, and ‘z’ are real numbers greater than or equal to 0 and less than 1, such that (x+y+z=1).

In some embodiment, the silicon film of FIG. 4B may have a chemical formula of SiₐO_{b}H_{c}D_{d}, wherein ‘a’, ‘b’, ‘c’, and ‘d’ are real numbers greater than or equal to 0 and less than 1, such that (a+b+c+d=1). Hydrogen atoms in the chemical formula of FIG. 4A may include both hydrogen resulting from a Si—H bond and hydrogen resulting from an O—H bond. Heavy hydrogen atoms in the chemical formula of FIG. 4B may be heavy hydrogen resulting from a Si—D bond formed by substituting a Si—H bond. Accordingly, Equation 1, Equation 2, Equation 3 and Equation 4 may be satisfied as:

x=a [Equation 1]

y=b [Equation 2]

z>c [Equation 3]

z=(c+d) [Equation 4]

Those skilled in the art will appreciate that the foregoing chemical formulas are merely examples, and chemical formulas of silicon films consistent with embodiments of the inventive concept are not limited thereto. For example, such silicon films may further include elements other than hydrogen (H), oxygen (O), and silicon (Si), and may contain impurities.

The silicon film formed by the substrate processing method 10 of FIG. 1 may include both Si—D bonds and O—H bonds. If the Si—D bond is detected in a state in which O—H functional groups are preserved by infrared absorption spectrum analysis, or the like, it can be determined that the substrate processing method according to the present inventive concept is applied.

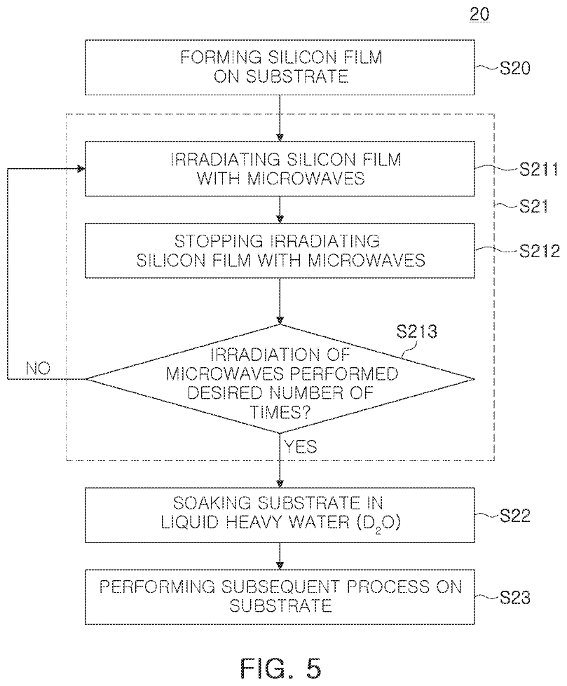

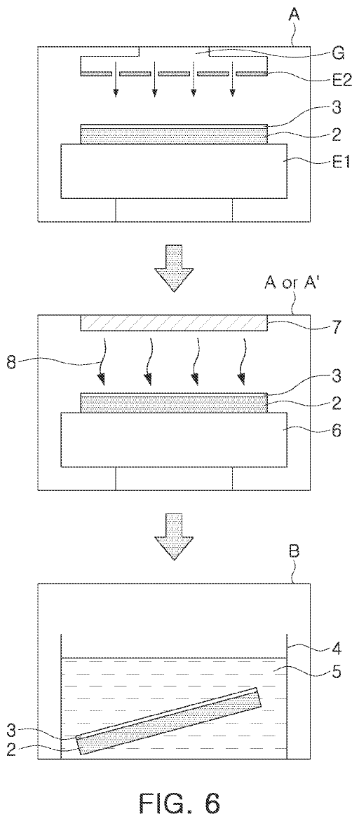

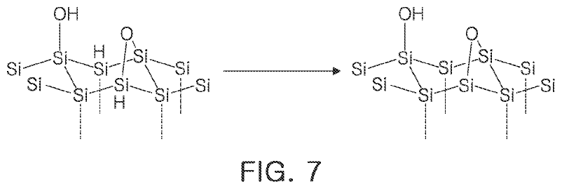

FIG. 5 is a flowchart illustrating a substrate processing method 20 according to embodiments of the inventive concept; FIG. 6 is a conceptual diagram further illustrating the substrate processing method 20 of FIG. 5; and FIG. 7 is a chemical structure diagram for a silicon film before and after application of the substrate processing method 20 of FIG. 1.

Referring to FIGS. 5 and 6, the substrate processing method 20 may include; forming the silicon film 3 on the substrate 2. (S20), irradiating the silicon film 3 with microwaves (S21), and soaking the substrate 2 in heavy liquid water (D₂O) (S22). In some embodiments, the substrate processing method 20 may further include performing an additional (or subsequent) process on the substrate 2 (S23).

Here, the substrate processing method 20 of FIG. 5 differs from the substrate processing method 10 of FIG. 1 in that the silicon film 3 is first irradiated with microwaves and then the substrate 2 including the, silicon film 3 is soaked in liquid heavy water.

As before, the silicon film 3 may be a polycrystalline silicon film formed on the substrate 2 using an atomic layer deposition (ALD) process, a chemical vapor deposition (CVD) process, etc.

Illustrated components of the conceptual diagram of FIG. 6 (e.g., first and second electrodes E1 and E2, gas supply unit 0, microwave generator 7, bath 4 and liquid heavy water 5) may be substantially the same as those described in relation to FIG. 2. However, the first processing chamber A may be used to perform method steps S20 and S21, and the second processing chamber B may be used to perform method step S22. Alternately, the first processing chamber A may be used to perform method step S20 and another processing chamber A′ may be used to perform method step S21.

Consistent with the foregoing description, the irradiation of the silicon film 3 with microwaves may be performed according to a defined number of irradiation cycles, each irradiation cycle having a predetermined duration, and successive irradiation cycles being separated by a defined period.

Of additional note in relation to the method of FIGS. 5 and 6, during the irradiating of the silicon film with microwaves (S21), the temperature of the silicon film 3 may rise into a temperature range of from about 423K to about 443K. In this regard, by irradiating the silicon film with microwave energy such that the temperature of the silicon film falls within the foregoing temperature range, impurities included within the substrate 2 may be desorbed, and Si—H bonds in the silicon film 3 may subsequently he during soaking of the substrate in liquid heavy water (S22). In some embodiments, when the silicon film 3 is a polycrystalline silicon film, as compared with cases wherein the silicon film 3 is an amorphous silicon film, the temperature increase associated with the second method step S21 may be relatively great, such that Si—H bonds removal reaction may be strongly promoted.

In some embodiment, the second method step (S21) may include sub-steps (S211), (S212) and (S213) which are respectively and substantially similar to method sub-steps (S121), (S122) and (S123) of FIG. 1.

Following the second method steps (S21), the substrate may be soaked in liquid heavy water (D₂O) (S22), wherein the silicon film 3 on the substrate 2 are immersed in the liquid heavy water (D₂O) after having been irradiated with microwaves. Referring to FIG. 6, the bath 4 containing the liquid heavy water 5 may be provided in the second processing chamber B.

By application of the second and third method steps S21 and S22, Si—H bonds included in the silicon film 3 may effectively be removed.

As may be understood from FIG. 7, a first exemplary chemical structure (left hand-side) for the silicon film 3 as formed on substrate 2 (S20) may be converted into a more robust, second chemical structure (right hand side) by immersing the substrate 2. in the bath 4 of liquid heavy water 5 (S22) after irradiating the silicon film 3 with microwaves (S21).

As illustrated in FIG. 7, by application of the second and third method steps S21 and S22, unstable Si—H bonds may be selectively removed, and stable O—H bonds may be maintained. By irradiating the silicon film with microwaves (S21), unpaired electrons scattered in the silicon film may be placed in an excited (or energized) state, such that the temperature of the silicon film 3 increases into a desired temperature range (e.g., a temperature ranging from about 423K to about 443K). As a result, impurities adsorbed to the silicon film 3 may be desorbed. However, in order to effectively desorb hydrogen (H) from silicon (Si) in the silicon film 3 in gas (e.g., air), the a temperature higher than the foregoing temperature range may be required. For example, in the case of Si—H₂ bonds in the silicon film 3 in gas, hydrogen may be desorbed in a temperature range of from about 640K to about 700K. Alternately or additionally, in the case of Si—H bonds in the silicon film in gas, hydrogen may be desorbed in a temperature range of from about 720K to about 800K. In the foregoing examples, the temperature was measured at the surface of the silicon film. By irradiating the silicon film 3 in gas with microwaves during the second method step (S21), hydrogen may not be sufficiently desorbed from silicon.

Accordingly, during the subsequently performed third method steps (S22), Si—H bonds may be effectively removed by soaking the silicon film 3, after heated by microwave irradiation, in the liquid heavy water (D₂O). Here, when the silicon film 3 has been heated to a temperature ranging from about 423K to about 443K during the second method steps (S21) and then immersed (or soaked) in the liquid heavy water at room temperature during the third method step (S22), the Si—H bonds in the silicon film will react with the liquid heavy water to generate gaseous phase vapor (HOD). And as a result, Si—H bonds included in the silicon film may be removed, and the silicon (Si) atoms associated with a surface layer of the silicon film 3 may reorganize as the temperature of the silicon film 3 is reduced. in this manner, dangling bonds on the surface of the silicon film may be reduced. Further, during the third method step (S22), liquid heavy water may serve as a reactant that causes an oxidation-reduction reaction of Si—H bonds in the silicon film 3. The liquid heavy water may also serve as a refrigerant that reduces the temperature of the silicon film 3, and prevents adsorption of water vapor (H₂O) in the air on the surface of the silicon film.

As described above, the second and third method steps S21 and S22 enable selective hydrogen removal. Microwaves irradiated to the silicon film can selectively vibrate unpaired electrons. Unstable Si—H bonds in which hydrogen ions and unpaired electrons of silicon are bonded by electrical attraction vibrate in response to application of the microwave energy, and may react with liquid heavy water. Other stable bonds, such as O—H bonds, will not be so markedly vibrated by application of the microwave energy. Accordingly, while maintaining stable O—H bonds, only unstable Si—H bonds may be selectively removed.

Thereafter, a subsequent process may be performed on the substrate (S23). Since unstable Si—H bonds have been removed by the preceding method steps, even when a high-temperature process such as heat treatment is performed after method step (S23), the phenomenon in which hydrogen (H) is desorbed from silicon (Si) and outgassed as hydrogen gas (H₂) will not occur, such that operating characteristics and reliability of the semiconductor device may be improved.

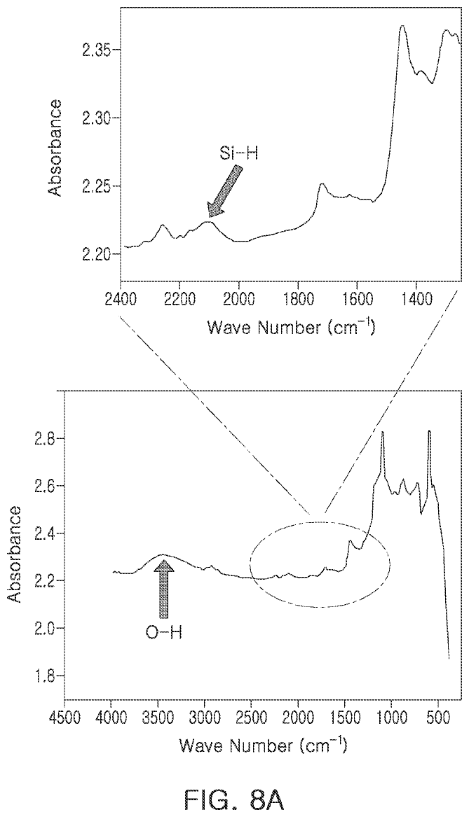

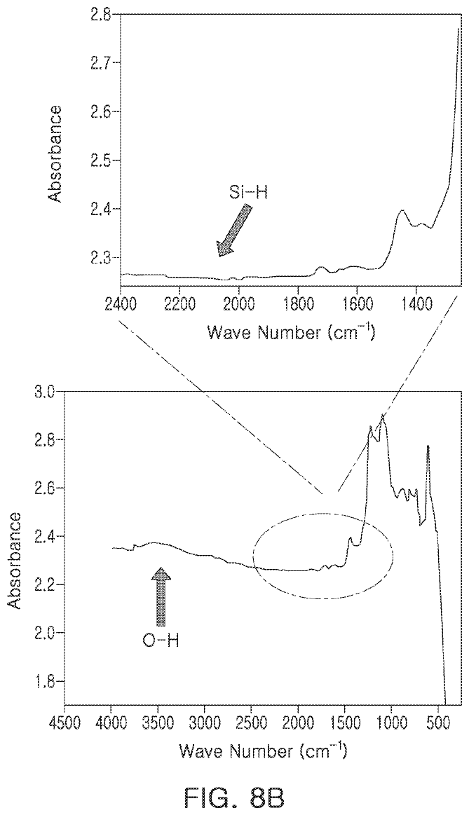

FIG. 8A is a graph illustrating an infrared absorption spectrum for the silicon film 3 formed during the first method step (S20); and FIG. 8B is a graph illustrating an infrared absorption spectrum for the silicon film 3 after the second and third method steps S21, and S22 have been performed.

During the second method steps (S21), the silicon film 3 is irradiated by microwaves, and subsequently during the third method step (S22), the silicon film—after being irradiated with microwaves—is soaked in liquid heavy water. Here, the silicon film may be cyclically irradiated with microwaves (S211) for periods lasting 15 seconds with successive irradiation cycles being separated by periods of non-irradiation (S212) lasted for 45 seconds. Once again, the microwave generator 7 may operate at a frequency of 2.45 GHz, a wavelength of 0.122 m, and a power of 700 W. In one particular example, ten (10) irradiation periods were used.

Referring to FIG. 8A, before Si—H bond removal reaction, an absorption peak appears at 2,280 cm⁻¹ to 2,050 cm⁻¹ and 3,400 cm⁻¹ to 3,200 cm⁻¹. It can be seen that there are Si—H bonds (2,280 cm-¹ to 2,050 cm⁻¹) and O—H bonds (3,400 cm⁻¹ to 3200 cm−¹) on the silicon film before a Si—H bond removal reaction.

Referring to FIG. 8B, after Si—H bond removal reaction, an absorption peak at 2,280 cm⁻¹ to 2,050 cm⁻¹ decreases, but an absorption peak at 3,400 cm⁻¹ to 3,200 cm⁻¹ is maintained. Accordingly, it can be seen that the Si—H bond (2,280 cm⁻¹ to 2,050 cm⁻¹) decreases, but the absorption peak at 3,400 cm⁻¹ to 3,200 cm⁻¹ is maintained. Unlike the examples illustrated in FIGS. 4A and 4B, Si—D bond (1,639 cm⁻¹) are not observed. Therefore, it may be confirmed that the Si—H bond is removed, rather than being substituted with Si—D.

In some embodiments, the silicon film of FIG. 8A may have a chemical formula of SixOyHz, wherein ‘x’, ‘y’, and ‘z’ are real numbers greater than or equal to 0 and less than 1, such that (x+y+z=1).

The silicon film of FIG. 8B may have a chemical formula of SiₚO_{q}Hᵣ, wherein ‘p’, ‘q’, and ‘r’ are real numbers greater than or equal to 0 and less than 1, such that (p+q+r=1).

A hydrogen atom in the chemical formula of FIG. 8A may include both hydrogen resulting from a Si—H bond and hydrogen resulting from an O—H bond. In the silicon film of FIG. 8A, the Si—H bond formed by the stable covalent bond may be maintained, and unstable Si—H bond electrically bonded with an unpaired electron of silicon is removed, so that a silicon film of FIG. 8B can be formed. Accordingly, a ratio of hydrogen atoms in the chemical formula of FIG. 8B may be smaller than a ratio of hydrogen atoms in the chemical formula of FIG. 8A. It follows that Equation 5, Equation 6 and Equation 7 are satisfied:

x<p [Equation 5]

y<q [Equation 6]

z>r [Equation 7]

Consistent with the foregoing, the above-described chemical formulas are presented as examples, and may further include elements other than hydrogen (H), oxygen (O), and silicon (Si), and may include impurities.

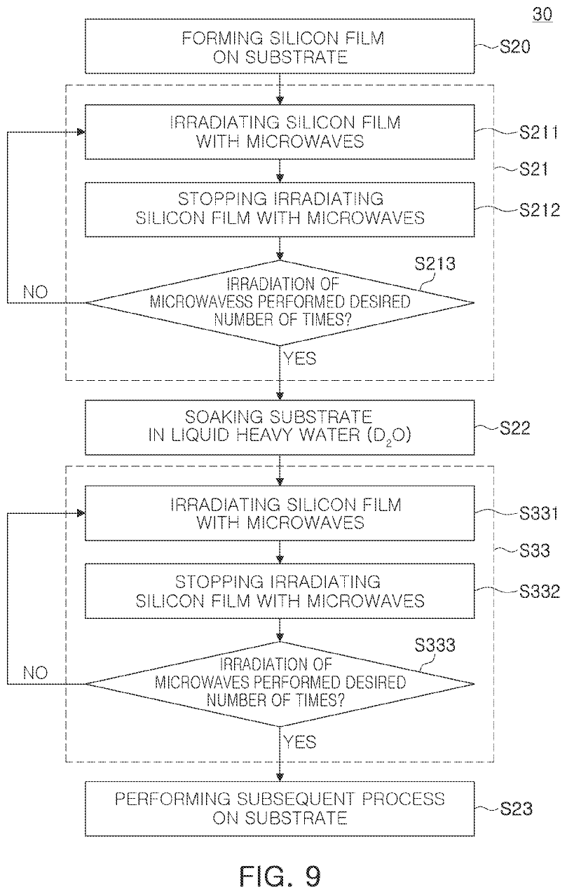

FIG. 9 is a flowchart illustrating a substrate processing method 30 according to embodiments of the inventive concept.

Here, the substrate processing method 30 of FIG. 9 includes the method steps S20, S21, S22 and S23 previously described in relation to the substrate processing method 20. However, the substrate processing method 30 of FIG. 9 additionally includes a method step S33 that is performed between the method steps of soaking of the substrate in liquid heavy water (S22) and the optionally performing method step of performing a subsequent process on the substrate (S23).

In this regard, the additional method step (S33) may be substantially similar that the method step S12 of FIG. 1, wherein a substrate soaking in liquid heavy water is irradiated with microwaves. As a result in some embodiment, the method sub-steps (S331), (S332) and (S333) associated with method step (S33) may be respectively and substantially similar to the method sub-steps (S121), (S122) and (S123) associated with method step (S12).

Accordingly, the substrate processing method 30 of FIG. 9 differs from the substrate processing method 20 of FIG. 5 in that a substrate including a target silicon film is additionally irradiated with microwaves while soaking in liquid heavy water after already having been irradiated with microwaves while in a gas (or air) environment. In this manner, the conditions, variations and benefits previously described in relation to the differing types of microwave irradiation may be realized in a single substrate.

That is, by additionally irradiating the silicon film with microwaves while soaking in liquid heavy water, Si—H bonds unreacted by the microwave irradiation in the gas environment (S21) may be replaced with Si—D bonds. in addition, silicon (Si) atoms having a dangling bond may be oxidized to have a Si—O—Si bond. Accordingly, unstable bonds existing in the silicon film may be either removed or replaced with stable bonds, thereby improving performance characteristics and reliability of the semiconductor device.

Upon review of the foregoing, those skilled in the art will appreciate that a substrate processing method according to embodiments of the inventive concept may generally include (1) forming a first material layer on a substrate, and (2) forming a second material layer from the first material layer by (a) irradiating the first material layer with microwaves and (b) soaking the first material layer in liquid heavy water (D₂O), wherein the first material layer includes a first compound of SiₓO_{y}H_{z}, wherein each of x, y, and z is real number greater than or equal to 0 and less than 1, such that (x+y+z=1), and the second material layer includes a second compound of SiₐO_{b}H_{c}D_{d}, wherein each of a, b, c, d is a real number greater than or equal to 0 and less than 1, such that (a+b+c+d=1). Here, in some embodiments, the method step of forming the second material layer from the first material layer may include the sub-step of irradiating the first material layer with microwaves before the sub-step of soaking the first material layer in liquid heavy water (D₂O). And in other embodiments, the method step of forming the second material layer from the first material layer may include the sub-step of irradiating the first material layer with microwaves after the sub-step of soaking the first material layer in liquid heavy water (D₂O).

Further, the method step of forming the second material layer from the first material layer may satisfy at least one the conditions: z>c; z=(c+d); x=a; and y=b.

Still further, the first material layer may include a Si—H functional group and an O—H functional group, whereas the second material layer includes an Si—D functional group and an O—H functional group.

As set forth above in relation to certain illustrated embodiments of the inventive concept, by removing or substituting deuterium for hydrogen unstably bonded to silicon, and bonding deuterium to a silicon unsaturated bond site, a substrate processing method for improving stability of the silicon film may be provided.

And while certain illustrated embodiments have been shown and described above, those skilled in the art will appreciate that many modifications and variations may be made to same without departing from the scope of the inventive concept as defined by the appended claims.

What is claimed is:

1. A substrate processing method, comprising of:
forming a silicon film on a substrate;
soaking the substrate on which the silicon film is formed in liquid heavy water; and
irradiating the silicon film with microwaves while the substrate soaks in the liquid heavy water.

2. The substrate processing method of claim 1, wherein the silicon film is a polycrystalline silicon film.

3. The substrate processing method of claim 1, wherein the irradiating of the silicon film with microwaves includes:
irradiating the silicon film with microwaves for a first period of time; and
stopping the irradiating of the silicon film with microwaves for a second period of time.

4. The substrate processing method of claim 3, wherein the first period of time ranges from about 10 seconds to about 20 seconds, and
the second period of time ranges from about 40 seconds to about 50 seconds.

5. The substrate processing method of claim 1, wherein the irradiating of the silicon film with microwaves includes cyclically irradiating the silicon film between 1 and 15 times.

6. The substrate processing method of claim 1, wherein during the irradiating of the silicon film with microwaves, the liquid heavy water has a temperature ranging from about 320K to about 373K.

7. The substrate processing method of claim 1, wherein the forming of the silicon film on the substrate is performed in a first processing chamber; and
the soaking of the substrate on which the silicon film is formed in liquid heavy water includes:
placing the substrate on which the silicon film is formed in a bath containing liquid heavy water; and then,
transferring the bath into a second processing chamber different from the first processing chamber.

8. The substrate processing method of claim 7, wherein the irradiating of the silicon film with microwaves while the substrate soaks in the liquid heavy water is performed in the second processing chamber.

9. A substrate processing method, comprising operations of:
forming a silicon film on a substrate;
irradiating the silicon film with microwaves; and
soaking the silicon film in liquid heavy seater.

10. The substrate processing method of claim 9, wherein the soaking of the silicon film in liquid heavy water is performed after the irradiating of the silicon film with microwaves.

11. The substrate processing method of claim 10, wherein during the irradiating of the silicon film with microwaves, the silicon film has a temperature ranging from about 423K to about 443K.

12. The substrate processing method of claim 9, wherein the irradiating of the silicon film with microwaves includes:
irradiating the silicon film with microwaves for a first period of time; and
stopping the irradiating of the silicon film with microwaves for a second period of time.

13. The substrate processing method of claim 9, wherein the irradiating of the silicon film with microwaves is cyclically performed between 1 and 15 times.

14. A substrate processing method, comprising:
forming a first material layer on a substrate; and
forming a second material layer from the first material layer by irradiating the first material layer with microwaves and soaking the first material layer in liquid heavy water (D₂O),
wherein the first material layer includes a first compound of SiₓO_{y}H_{z}, wherein each of x, y, and z is real number greater than or equal to 0 and less than 1, such that (x+y+z=1), and
the second material layer includes a second compound of SiₐO_{b}H_{c}D_{d}, wherein each of a, b, c, d is a real number greater than or equal to 0 and less than 1, such that (a+b+c+d=1).

15. The substrate processing method of claim 14, wherein z>c is satisfied.

16. The substrate processing method of claim 14, wherein each one of z=c+d); x=a; and y=b is satisfied.

17. The substrate processing method of claim 14, wherein the first material layer comprises a Si—H functional group and an O—H functional group, and
the second material layer comprises an Si—D functional group and an O—H functional group.

18. The substrate processing method of claim 14, wherein during the forming of the second material layer from the first material, the first material layer is irradiated with microwaves while the first material layer soaks in the liquid heavy water (D₂O).

19. The substrate processing method of claim 14, wherein during the forming of the second material layer from the first material, the irradiating of the first material layer with microwaves is performed according to a number of irradiation cycles.

20. The substrate processing method of claim 14, wherein the first material layer is polycrystalline silicon.
